(19) United States
(12) Patent Application Publication
(10) Pub. No.: US 2025/0293708 A1
(43) Pub. Date: Sep. 18, 2025

(54) Method for Compressing and Serializing Complex Time Series Data

(71) Applicant: WaveXR, Inc., Los Angeles, CA (US)

(72) Inventor: Sean Dunn, Austin, TX (US)

(73) Assignee: WaveXR, Inc., Los Angeles, CA (US)

(21) Appl. No.: 19/082,750

(22) Filed: Mar. 18, 2025

Related U.S. Application Data
(60) Provisional application No. 63/566,468, filed on Mar. 18, 2024.

(51) Int. Cl. H03M 7/30; H03M 9/00

(52) U.S. Cl. CPC H03M 7/70; H03M 9/00

(57) ABSTRACT

A method for compressing and serializing data, the method comprising: inputting raw data; the raw digital data is configured to be define a schema; the schema is a model of data to be transmitted; the raw data is defined as a value, an array, or a structure; the header code of the data is mapped to a special value; serializing; the raw data is converted; serialization tracks whether a key frame or a delta frame is written; special data values have only header code written; post-processing; the written data stream is block compressed; and de-serializing; a received bit stream is converted into a lossy data; the data type is read; the schema is followed; wherein the header code is read.

### CROSS REFERENCE PARAGRAPH

This U.S. Non-Provisional patent application claims the benefit of and priority to U.S. Provisional Patent Application No. 63/566,468, filed on Mar. 18, 2024, by inventor Sean Dunn, the contents of which are expressly incorporated herein by this reference.

### FIELD OF USE

The present disclosure relates, in general, to a method of compressing and serializing data. More specifically, the present disclosure relates to a method of tuning and storing each piece of data for mathematical data compression that can further be compressed by a post process.

### BACKGROUND

Transmitting motion captured data is an important problem in live performances. Compressed audio, body motion capture, face capture, visual FX animation, object properties, interactive polling results must be efficiently compressed, transmitted, received, and decompressed as well as optionally archived and replayed at a later date.

Typically, transmitted data is platform dependent and may include many different data-types e.g., compressed audio, body motion capture, face capture, visual FX animation, object properties, interactive polling results.

Declarative languages exist for structuring this data (e.g., JSON, XML), as well as third party libraries for describing data schemas (Google Protobuffers), the base data-types therein are general purpose. Techniques exist for reducing the sizes of encoded integer data based on bytes required (i.e., Google Protobuffer variant types), but there is no sense of the range in which the data will be used, or how that data can be compared against itself for further compression.

Therefore, what is needed is a new method of data compression that allows creating custom data-types that can be compressed using application of type specific knowledge, in a structured format, and further compressed.

### SUMMARY

To minimize the limitations in the prior art, and to minimize other limitations that will become apparent upon reading and understanding the present specification, the present disclosure discloses a new and useful method of compressing and serializing data.

The following presents a simplified overview of the example embodiments in order to provide a basic understanding of some embodiments of the example embodiments. This overview is not an extensive overview of the example embodiments. It is intended to neither identify key or critical elements of the example embodiments nor delineate the scope of the appended claims. Its sole purpose is to present some concepts of the example embodiments in a simplified form as a prelude to the more detailed description that is presented herein below. It is to be understood that both the following general description and the following detailed description are exemplary and explanatory only and are not restrictive.

One embodiment may be a method for compressing and serializing data, the method comprising: inputting raw data; wherein the raw digital data may be configured to be defined; defining a schema; wherein the schema is a model of data to be transmitted; wherein the raw data may be defined as a value, an array, or a structure; wherein the minimum and maximum values of the data are represented as their original values; wherein the floating point values of the data are converted to a unit parametric value representing the input value's minimum to maximum range; wherein the header code of the data is mapped to a special value; serializing; wherein the raw data may be converted based on the schema; wherein serialization tracks whether a key frame or a delta frame is written; wherein special data values have only header code written; post-processing; wherein the written data stream is block compressed; and de-serializing; wherein a received bit stream is converted into a lossy data based on the schema; wherein the data type is read; wherein the schema is followed; wherein the header code is read. The key frame value may be an absolute value, and the delta frame value is a relative value. The relative value may be a mathematical difference between a current integer-converted value and a last key frame value. The schema may assign to each of the raw data a type-kind selected from the group consisting of a value, an array, and a struct (which is short for structure, which is a way to group several related variables into one place).

One embodiment may be a method for compressing and serializing data, the method comprising: providing a data; defining a schema for one or more data-types; structuring the data into one or more sub-data components corresponding to the one or more data-types; serializing the sub-data components by assigning to each frame of the sub-data a key frame value or a delta frame value; transmitting the serialized data from a first electronic device; receiving the serialized data at a second electronic device; and de-serializing the serialized data. The key frame value may be an absolute value, and the delta frame value is a relative value. The relative value may be a mathematical difference between a current integer-converted value and a last key frame value. The schema may assign to each of the one or more data-types a type-kind selected from the group consisting of a value, an array, and a struct. The value may comprise a single integer value. The array may comprise a variable number of values. The struct may comprise a set sequence of individual values. The one or more data-types may comprise a kind, a numeric type ID, a min value, a max value, and one or more header codes. The one or more header codes may comprise a special value. The one or more header codes may comprise a specific bit width.

To solve the problem of efficiently compressing, transmitting, receiving, and decompressing live data the disclosed method reaches high compression by allowing the application developer to tune the quality for each piece of data, as well as storing the data in order to be mathematically delta compressed. The resulting string of 0 bits for values which have not changed can further be compressed by post processing via the use of algorithms, such as a dictionary-matching algorithm.

In one embodiment, the present disclosure may be used to send live structured data over a network as a sequence of compressed frames. Each value in the data structure for a frame may have local requirements for signal quantization quality. It may be preferable to use a consistent description of each type so that it can resolve to a differentiable bit sequence, which can be delta compressed over time, and then subsequently block compressed. In one embodiment, a structure may contain a color value (high quantization), a 3D transform (low quantization), and a string (no quantization). In some embodiments, it may be possible to compress the quantized values in time by using key and delta frames. Delta frames may be the difference between the current frame and the last key frame. Delta frames may contain values with no change from the same value in the last key frame, which would resolve to sequences of 0 bits. These sequences of 0 bits may be compressed even further using a general-purpose compression algorithm.

These, as well as other components, steps, features, objects, benefits, and advantages, will now become clear from a review of the following detailed description of illustrative embodiments, the accompanying drawings, and the claims.

### BRIEF DESCRIPTION OF THE DRAWINGS

The drawings are of illustrative embodiments. They do not illustrate all embodiments. Other embodiments may be used in addition or instead. Details which may be apparent or unnecessary may be omitted to save space or for more effective illustration. Some embodiments may be practiced with additional components or steps and/or without all of the components or steps which are illustrated. When the same numeral appears in different drawings, it refers to the same or like components or steps.

FIG. 1 is a flow block diagram of the method of the compression algorithm.

FIG. 2 is a flow block diagram of the preferred embodiment of the present disclosure.

FIG. 3. is a flowchart of one embodiment of a method for compressing and serializing data.

### DETAILED DESCRIPTION OF THE ILLUSTRATIVE EMBODIMENTS

In the following detailed description of various embodiments of the present disclosure, numerous specific details are set forth in order to provide a thorough understanding of various aspects of one or more embodiments of the present disclosure. However, one or more embodiments of the present disclosure may be practiced without some or all of these specific details. In other instances, well-known methods, procedures, and/or components have not been described in detail so as not to unnecessarily obscure aspects of embodiments of the present disclosure.

While multiple embodiments are disclosed, still other embodiments of the devices, systems, and methods of the present disclosure will become apparent to those skilled in the art from the following detailed description, which shows and describes illustrative embodiments of the devices, systems, and methods of the present disclosure. As will be realized, the devices, systems, and methods of the present disclosure are capable of modifications in various obvious aspects, all without departing from the spirit and scope of the present disclosure. Accordingly, the screenshot figures, and the detailed descriptions thereof, are to be regarded as illustrative in nature and not restrictive. Also, the reference or non-reference to a particular embodiment of the devices, systems, and methods of the present disclosure shall not be interpreted to limit the scope of the present disclosure.

Before the present methods and systems are disclosed and described, it is to be understood that the methods and systems are not limited to specific methods, specific components, or to particular implementations. It is also to be understood that the terminology used herein is for the purpose of describing particular embodiments only and is not intended to be limiting.

As used in the specification and the appended claims, the singular forms “a,” “an,” and “the” include plural referents unless the context clearly dictates otherwise. Ranges may be expressed herein as from “about” one particular value, and/or to “about” another particular value. When such a range is expressed, another embodiment includes from the one particular value and/or to the other particular value. Similarly, when values are expressed as approximations, by use of the antecedent “about,” it will be understood that the particular value forms another embodiment. It will be further understood that the endpoints of each of the ranges are significant both in relation to the other endpoint, and independently of the other endpoint.

“Optional” or “optionally” means that the subsequently described event or circumstance may or may not occur, and that the description includes instances where said event or circumstance occurs and instances where it does not.

Throughout the description and claims of this specification, the word “comprise” and variations of the word, such as “comprising” and “comprises,” means “including but not limited to,” and is not intended to exclude, for example, other components, integers, or steps. “Exemplary” means “an example of” and is not intended to convey an indication of a preferred or ideal embodiment. “Such as” is not used in a restrictive sense, but for explanatory purposes.

Disclosed are components that may be used to perform the disclosed methods and systems. These and other components are disclosed herein, and it is understood that when combinations, subsets, interactions, groups, etc. of these components are disclosed that while specific reference of each various individual and collective combinations and permutation of these may not be explicitly disclosed, each is specifically contemplated and described herein, for all methods and systems. This applies to all embodiments of this application including, but not limited to, steps in disclosed methods. Thus, if there are a variety of additional steps that may be performed it is understood that each of these additional steps may be performed with any specific embodiment or combination of embodiments of the disclosed methods.

The present methods and systems may be understood more readily by reference to the following detailed description of preferred embodiments and the examples included therein and to the Figures and their previous and following description.

In the following description, certain terminology is used to describe certain features of one or more embodiments. For purposes of the specification, unless otherwise specified, the term “substantially” refers to the complete or nearly complete extent or degree of an action, characteristic, property, state, structure, item, or result. For example, in one embodiment, an object that is “substantially” located within a housing would mean that the object is either completely within a housing or nearly completely within a housing. The exact allowable degree of deviation from absolute completeness may in some cases depend on the specific context. However, generally speaking, the nearness of completion will be so as to have the same overall result as if absolute and total completion were obtained. The use of “substantially” is also equally applicable when used in a negative connotation to refer to the complete or near complete lack of an action, characteristic, property, state, structure, item, or result.

As used herein, the terms “approximately” and “about” generally refer to a deviance of within 5% of the indicated number or range of numbers. In one embodiment, the term “approximately” and “about”, may refer to a deviance of between 0.001-10% from the indicated number or range of numbers.

Various embodiments are now described with reference to the drawings. In the following description, for purposes of explanation, numerous specific details are set forth in order to provide a thorough understanding of one or more embodiments. It may be evident, however, that the various embodiments may be practiced without these specific details. In other instances, well-known structures and devices are shown in block diagram form to facilitate describing these embodiments.

Furthermore, the one or more versions may be implemented as a method, apparatus, or article of manufacture using standard programming and/or engineering techniques to produce an entirely hardware embodiment, an entirely software embodiment, or an embodiment combining software and hardware embodiments. Furthermore, the systems and methods may take the form of non-transitory computer readable media. More particularly, the present methods and systems may take the form of web-implemented computer software or a computer program product. Any suitable computer-readable storage medium may be utilized including, but are not limited to, magnetic storage devices (e.g., hard disk, floppy disk, magnetic strips), optical disks (e.g., compact disk (CD), digital versatile disk (DVD)), smart cards, and flash memory devices (e.g., card, stick).

Those skilled in the art will recognize that many modifications may be made to this configuration without departing from the scope of the disclosed embodiments.

Embodiments of the systems and methods are described below with reference to schematic diagrams, block diagrams, and flowchart illustrations of methods, systems, apparatuses, and computer program products. It will be understood that each block of the block diagrams, schematic diagrams, and flowchart illustrations, and combinations of blocks in the block diagrams, schematic diagrams, and flowchart illustrations, respectively, may be implemented by computer program instructions. These computer program instructions may be loaded onto a general-purpose computer, special purpose computer, or other programmable data processing apparatus to produce a machine, such that the instructions which execute on the computer or other programmable data processing apparatus create a means for implementing the functions specified in the flowchart block or blocks.

These computer program instructions may also be stored in a computer-readable memory that may direct a computer or other programmable data processing apparatus to function in a particular manner. The computer program instructions may also be loaded onto a computer or other programmable data processing apparatus to cause a series of operational steps to be performed on the computer or other programmable apparatus to produce a computer-implemented process such that the instructions that execute on the computer or other programmable apparatus provide steps for implementing the functions specified in the flowchart block or blocks.

Accordingly, blocks of the block diagrams and flowchart illustrations support combinations of means for performing the specified functions, combinations of steps for performing the specified functions and program instruction means for performing the specified functions. It will also be understood that each block of the block diagrams and flowchart illustrations, and combinations of blocks in the block diagrams and flowchart illustrations, may be implemented by special purpose hardware-based computer systems that perform the specified functions or steps, or combinations of special purpose hardware and computer instructions.

In the following description, certain terminology is used to describe certain features of the various embodiments of the device, method, and/or system. For example, as used herein, the terms “computer” and “computer system” generally refer to any device that processes information with an integrated circuit chip and/or central processing unit (CPU).

As used herein, the terms “software” and “application” refer to any set of machine-readable instructions on a machine, web interface, and/or computer system” that directs a computer's processor to perform specific steps, processes, or operations disclosed herein.

As used herein, the term “computer-readable medium” refers to any storage medium adapted to store data and/or instructions that are executable by a processor of a computer system. The computer-readable storage medium may be a computer-readable non-transitory storage medium and/or any non-transitory data storage circuitry (e.g., buggers, cache, and queues) within transceivers of transitory signals. The computer-readable storage medium may also be any tangible computer readable medium. In various embodiments, a computer readable storage medium may also be able to store data, which is able to be accessed by the processor of the computer system.

The disclosure relates to a method for serializing structured time series data. The method defines a component data schema for each application-specific quality.

During transmission of the data the method may interpret the data as a ranged integer, quantize, delta encode, and bit pack the data.

During reception of the data the method may unpack data bits, delta decode, dequantize, and interpret ranged integer to obtain a lossy presentation of what was sent. Special values can be defined in the schema which are detected, transmitted, and reconstructed without loss. Through lossy quantization, we have measured up to a 90% reduction in bandwidth on transmitted data.

Schema: models the data to be transmitted, with configuration for quality/space tradeoff.

Serializer: converts application data into a compressed bitstream based on the schema.

De-serializer: converts a bitstream into lossy application data, based on the schema.

The disclosure provides for a low-level control over the interpretation and quantization of data, describes common special values to reduce bitrate, and combines mathematical delta encoding to reduce bandwidth.

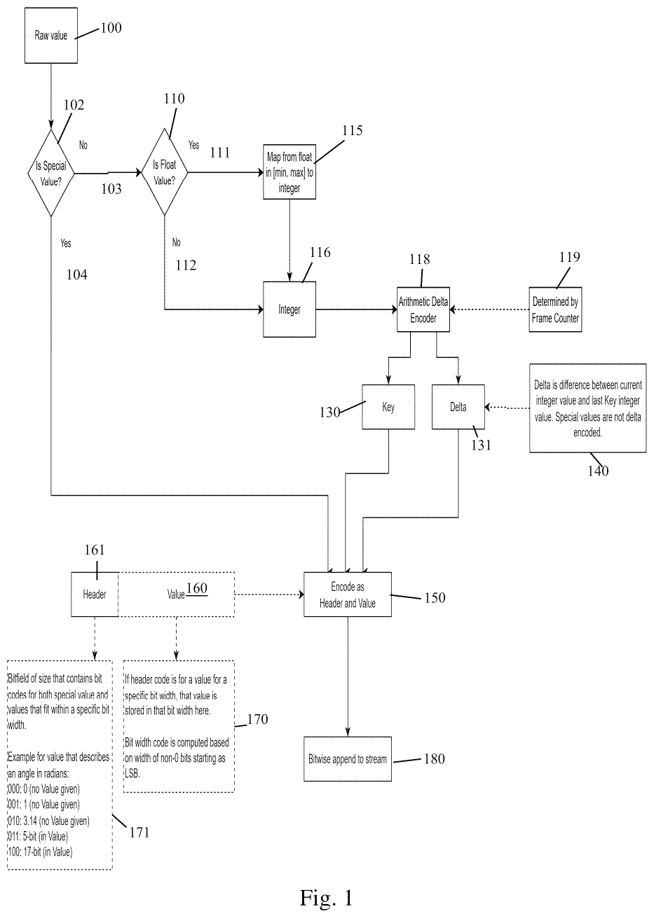

FIG. 1 is a flow block diagram of the method of the compression algorithm. As shown in FIG. 1, the algorithm may comprise: providing a raw data value 100 and determining if it is a special value 102. If yes 104, then encode as header and value 150. If no 103, then determine if it is a float value 110. If no, then integer 116. If yes 111, then map from float 115, in min, max, to integer 116. The Integer may be processed by arithmetic delta encoder 118, optionally as determined by frame counter 119. Serialization tracks whether data is being written as a key 130 or delta 131 frame. Delta is difference between current integer value and last key integer value. Special values are not delta encoded 140. Header 161 (bitfield of size that contains bit codes for both special value and values that fit within a specific bit width 171, example for value that describes an angle in radians: 0: 0 (no value given); 001: 1 (no value given); 010: 3.14 (no value given); 011: 5-bit (in value); 100: 17-bit (in value). Value 160 (if header codes is for a value for a specific bit width, that is value stored in that bit width 170 (bit width code is computed based on width of non-0 bits starting as LSB). Bitwise append to stream 180.

The general compression algorithm may include:

1) Inputting raw data. Raw data may be in the form of data bit streams. In some embodiments, other types of data, such as structured data, may be used.

2) Defining a schema that describes all valid types of data that may be compressed. Each type of data is defined as a kind, numeric type ID, min and max values, and a set of header codes. Each data kind may comprise a value, an array, or a structure. Data-types may include, but are not limited to, compressed audio, body motion capture, face capture, visual FX animation, object properties, interactive polling results. An array is a collection of data items of the same type, whereas a structure is a collection of data items of different types. A value can hold a single integer value. The min (minimum) and max (maximum) value may be stored in its original form. Floating point values may be converted to a unit parametric value that is then distributed across the floating point value's min, max range, as an integer within for the bits it can be stored in. Exponential data in the floating-point format may be lost, but in practice performance data typically exists within a limited range of magnitudes. Each header code may be mapped to either a special value or a specific bit width. If a special value is detected on the input, only the special value code is used. Otherwise, the value may be compared with bit width codes, and the code with the minimum supporting bit width for that value's bit width is used. If there are no defined special values and only a single bit width code, it is understood that that specific bit width is used for this type, without any header codes needed. This allows for efficiently storing arrays of bytes with no per-value headers.

In one embodiment, the minimum and maximum values of the input type may be stored in the type schema. In some embodiments, the floating point value may be converted to a clamped normalized form based on the minimum and maximum values. The normalized value may then be distributed linearly across the value range of an unsigned integer of a specific bit width. This may result in the minimum floating point value for the type corresponding to all 0 bits in the integer, and the maximum floating point value for the type corresponding to all 1 bits in the integer. In one embodiment, if the value 4.999 with a min, max range of 0.0, 10.0 was stored in an 8 bit width type, then it would serialize to the binary 00001111, which corresponds to the decimal integer 127.

3) Serialization, data may be written following the defined schema. Serialization tracks whether data is being written as a key or delta frame. Key frame values are absolute, based on the input. Delta frame values take the mathematical difference between the current integer-converted value and the last key frame value. For a special value, only a header code may be written. If the header code implies a bit width value, that value is written at the given number of bits. If a delta value must subsequently write a non-special value, relative to a special-value key frame, the absolute value as the delta is written, as if the key frame were zero. Writes are not aligned to bytes, and odd bit widths can cross byte boundaries. A post-process block compressor is applied to the final stream, to reduce data further. No type of information is required beyond the initial root type. Arrays must store their size in the bitstream, structures may be schema ordered. There are no union or any-style types.

4) De-serializing: the root type is read, and deserialization follows the schema structure. The header code is read: type one, results in, a directly used special value or a bit width, followed by the reading of that number of bits. If a delta frame is read, add these bits to the last received key frame's integer value. If the last received key frame integer value was a special value, interpret the delta value as an absolute non-relative value, as if the key frame were zero. The final integer bits may be converted back into their original value using the min and max values for the type.

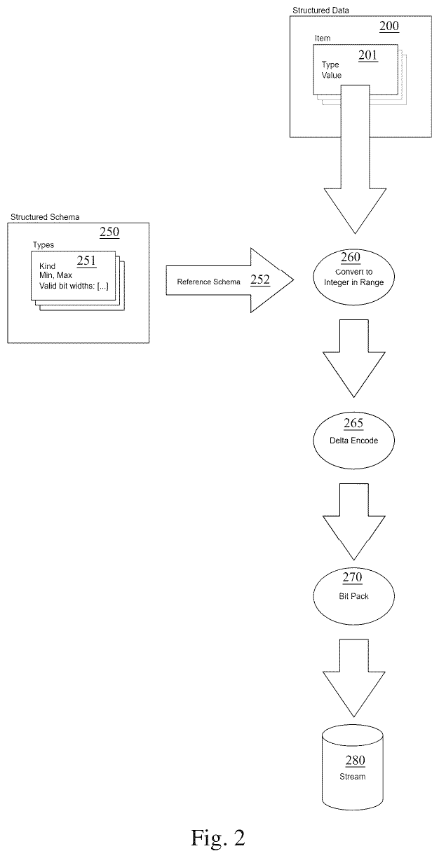

FIG. 2 is a flow block diagram of the data structure embodiment of the present disclosure. As shown in FIG. 2, structured data 200 is input by item 201 with a type and value. Structured Schema 250 is defined with types 251 with kind, min./max, and a valid bit width. Reference schema 252 converts data to integer in range 260, followed by delta encode, followed by bit pack 270, providing stream 280.

The method of data structure compression shown in FIG. 2 may include:

1) Inputting structured data.

2) Defining a schema for all data-types. Each type has a specific kind of data, type ID, min and max values, and header codes. For example: UTF8 string data and opaquely compressed audio packets are both described as arrays of 8 bit data integer values, would be given a data type ID 1; a floating point “small” value with at least 0.01 of precision may be described as a value between −16.0 and +16.0, within a value bitfield of 11 bits (4 bits value+7 bits fraction), would be given a data type ID 2; and a 3D small vector may then be described as a structure with three small floating point values (type ID 2), would be give a data type ID 3.

3) Serialization and De-serialization of data to be transmitted or received using an integrated application. All written application data values may be described as either integer or floating-point data. The serializer and de-serializer may be called as needed within the application runtime.

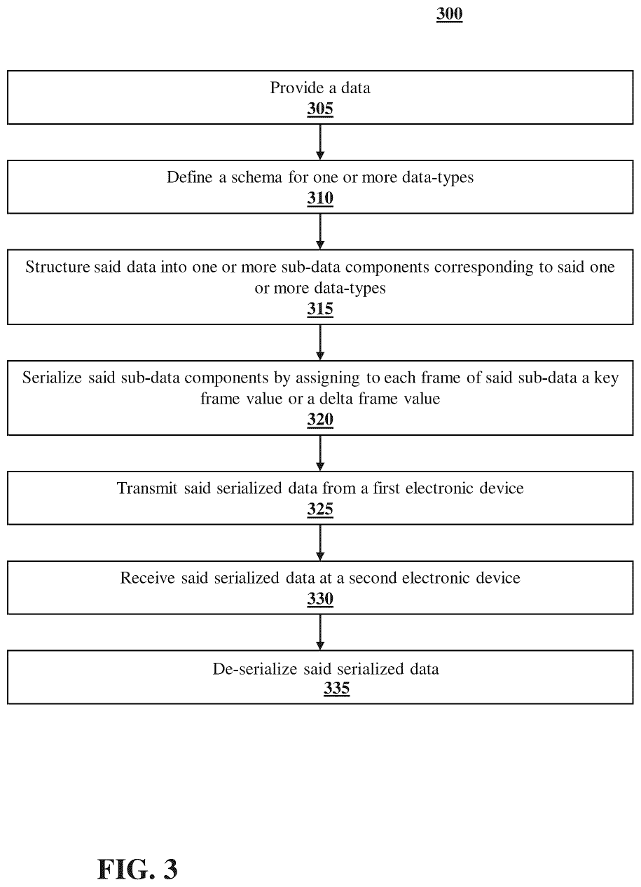

FIG. 3. is a flowchart of one embodiment of a method for compressing and serializing data. In some embodiments one or more process blocks of FIG. 3 may be performed by a device.

As shown in FIG. 3 the method 300 may include providing data 305. The method 300 may include defining a schema for one or more data-types 310. The method 300 may include structuring the data into one or more sub-data components corresponding to the one or more data-types 315. The method 300 may include serializing the sub-data components by assigning to each frame of the sub-data a key frame value or a delta frame value 320. The method 300 may include transmitting the serialized data from a first electronic device 325. The method 300 may include receiving the serialized data at a second electronic device 330. The method 300 may include de-serializing the serialized data 335.

The key frame value may be an absolute value, and the delta frame value may be a relative value. The relative value may be a mathematical difference between a current integer-converted value and a last key frame value. The schema may assign to each of the one or more data-types a type-kind selected from the group of a value an array and a struct. The value may include a single integer value. The array may include a variable number of values. The struct may include a set sequence of individual values. The one or more data-types may include a kind a numeric type ID a min value a max value and one or more header codes. The one or more header codes may comprise a special value. The one or more header codes may comprise a specific bit width.

In some embodiments, the method 300 may be used to compress data associated with live performances and transmit the compressed data for decompression at a different location quickly, such that the data may be used to create a substantially contemporaneous display of the live performance at a different location. The present method may also be used to transfer data relatively quickly.

Although FIG. 3 shows example blocks of the method 300 in some embodiments the method 300 may include additional blocks, fewer blocks, different blocks, or differently arranged blocks than those depicted in FIG. 3.

Unless otherwise stated, all measurements, values, ratings, positions, magnitudes, sizes, locations, and other specifications that are set forth in this specification, including in the claims that follow, are approximate, not exact. They are intended to have a reasonable range that is consistent with the functions to which they relate and with what is customary in the art to which they pertain.

Some portions of the preceding detailed descriptions have been presented in terms of algorithms and symbolic representations of operations on data bits within a computer memory. These algorithmic descriptions and representations are the means used by those skilled in the data processing arts to most effectively convey the substance of their work to others skilled in the art. An algorithm is here, and generally, conceived to be a self-consistent sequence of operations leading to a desired result. The operations are those requiring physical manipulations of physical quantities.

It should be borne in mind, however, that all of these and similar terms are to be associated with the appropriate physical quantities and are merely convenient labels applied to these quantities. Unless specifically stated otherwise as apparent from the above discussion, it should be appreciated that throughout the present disclosure, discussions utilizing terms such as those set forth in the claims below, refer to the action and processes of a computer system, or similar electronic computing device, that manipulates and transforms data represented as physical (electronic) quantities within the computer system's registers and memories into other data similarly represented as physical quantities within the computer system's memories or registers or other such information storage, transmission or display devices.

The processes or methods depicted in the figures may be performed by processing logic that comprises hardware (e.g., circuitry, dedicated logic, etc.), firmware, software (e.g., embodied on a non-transitory computer readable medium), or a combination thereof. Although the processes or methods are described above in terms of some sequential operations, it should be appreciated that some of the operations described may be performed in a different order. Moreover, some operations may be performed in parallel rather than sequentially.

In addition, the various illustrative logical blocks, modules, and circuits described in connection with certain embodiments disclosed herein may be implemented or performed with a general purpose processor, a digital signal processor (DSP), an application specific integrated circuit (ASIC), a field programmable gate array (FPGA) or other programmable logic device, discrete gate or transistor logic, discrete hardware components, or any combination thereof designed to perform the functions described herein. A general-purpose processor may be a microprocessor, but in the alternative, the processor may be any conventional processor, controller, microcontroller, system-on-a-chip, or state machine. A processor may also be implemented as a combination of computing devices, e.g., a combination of a DSP and a microprocessor, a plurality of microprocessors, one or more microprocessors in conjunction with a DSP core, or any other such configuration.

Operational embodiments disclosed herein may be embodied directly in hardware, in a software module executed by a processor, or in a combination of the two. A software module may reside in RAM memory, flash memory, ROM memory, EPROM memory, EEPROM memory, registers, hard disk, a removable disk, a CD-ROM, a DVD disk, or any other form of storage medium known in the art. An exemplary storage medium is coupled to the processor such the processor may read information from, and write information to, the storage medium. In the alternative, the storage medium may be integral to the processor. The processor and the storage medium may reside in an ASIC or may reside as discrete components in another device.

Furthermore, the one or more versions may be implemented as a method, apparatus, or article of manufacture using standard programming and/or engineering techniques to produce software, firmware, hardware, or any combination thereof to control a computer to implement the disclosed embodiments. Non-transitory computer readable media may include but are not limited to magnetic storage devices (e.g., hard disk, floppy disk, magnetic strips), optical disks (e.g., compact disk (CD), digital versatile disk (DVD)), smart cards, and flash memory devices (e.g., card, stick). Those skilled in the art will recognize many modifications may be made to this configuration without departing from the scope of the disclosed embodiments.

The foregoing description of the preferred embodiment has been presented for the purposes of illustration and description. While multiple embodiments are disclosed, still other embodiments will become apparent to those skilled in the art from the above detailed description. These embodiments are capable of modifications in various obvious aspects, all without departing from the spirit and scope of protection. Accordingly, the detailed description is to be regarded as illustrative in nature and not restrictive. Also, although not explicitly recited, one or more embodiments may be practiced in combination or conjunction with one another. Furthermore, the reference or non-reference to a particular embodiment shall not be interpreted to limit the scope of protection. It is intended that the scope of protection not be limited by this detailed description, but by the claims and the equivalents to the claims that are appended hereto.

Except as stated immediately above, nothing that has been stated or illustrated is intended or should be interpreted to cause a dedication of any component, step, feature, object, benefit, advantage, or equivalent, to the public, regardless of whether it is or is not recited in the claims.

What is claimed is:

1. A method for compressing and serializing data, the method comprising:
inputting a raw data, wherein said raw data is configured to be defined;
defining a schema, wherein said schema is a model of data to be transmitted;
wherein said raw data is defined as a value, an array, or a structure;
wherein a minimum value and a maximum value of said data are stored in their original form;
wherein one or more floating point values of said data are converted to a unit parametric value that represents a minimum to maximum range;
wherein a header code of said data is mapped to a special value;
serializing, wherein said raw data is converted based on said schema;
wherein serialization tracks whether a key frame or a delta frame is written;
wherein special data values have only header code written;
post-processing, wherein said converted data is block compressed; and
de-serializing, wherein a received bit stream is converted into a lossy data based on said schema;
wherein a data type is read;
wherein said schema is followed;
wherein said header code is read.

2. The method for compressing and serializing data of claim 1, wherein said key frame is an absolute value and said delta frame is a relative value.

3. The method for compressing and serializing data of claim 2, wherein said relative value is a mathematical difference between a current integer-converted value and a last key frame value.

4. The method for compressing and serializing data of claim 1, wherein said schema assigns to each of said raw data a type-kind selected from the group consisting of: a value; an array; and a struct.

5. A method for compressing and serializing data, the method comprising:
providing a data;
defining a schema for one or more data-types;
structuring said data into one or more sub-data components corresponding to said one or more data-types;
serializing said sub-data components by assigning to each frame of said sub-data components a key frame value or a delta frame value;
transmitting said serialized data from a first electronic device;
receiving said serialized data at a second electronic device; and
de-serializing said serialized data.

6. The method of claim 5, wherein said key frame value is an absolute value and said delta frame value is a relative value.

7. The method of claim 6, wherein said relative value is a mathematical difference between a current integer-converted value and a last key frame value.

8. The method of claim 7, wherein said schema assigns to each of said one or more data-types a type-kind selected from the group consisting of: a value; an array; and a struct.

9. The method of claim 8, wherein said value comprises a single integer value.

10. The method of claim 9, wherein said array comprises a variable number of values.

11. The method of claim 10, wherein said struct comprises a set sequence of individual values.

12. The method of claim 11, wherein said one or more data-types comprise a kind, a numeric type ID, a min value, a max value, and one or more header codes.

13. The method of claim 12, wherein said one or more header codes comprise a special value.

14. The method of claim 13, wherein said one or more header codes comprise a specific bit width.

15. A method for compressing and serializing data, the method comprising:
providing a data;
defining a schema for one or more data-types;
structuring said data into one or more sub-data components corresponding to said one or more data-types;
serializing said sub-data components by assigning to each frame of said sub-data components a key frame value or a delta frame value, such that a serialized data is created; and
de-serializing said serialized data.

16. The method of claim 15, further comprising:
transmitting said serialized data from a first electronic device; and
receiving said serialized data at a second electronic device.

17. The method of claim 16, wherein said key frame value is an absolute value and said delta frame value is a relative value.

18. The method of claim 17, wherein said relative value is a mathematical difference between a current integer-converted value and a last key frame value.

19. The method of claim 18, wherein said schema assigns to each of said one or more data-types a type-kind selected from the group consisting of: a value; an array; and a struct.
